(19) United States
(12) Patent Application Publication
(10) Pub. No.: US 2015/0179915 A1
(43) Pub. Date: Jun. 25, 2015

(54) Fluorine Passivation During Deposition of Dielectrics for Superconducting Electronics

(71) Applicant: INTERMOLECULAR, INC., San Jose, CA (US)

(72) Inventors: Frank Greer, Pasadena, CA (US); Sergey Barabash, San Jose, CA (US); Dipankar Pramanik, Saratoga, CA (US); Andrew Steinbach, San Jose, CA (US)

(73) Assignee: INTERMOLECULAR, INC., San Jose, CA (US)

(21) Appl. No.: 14/138,909

(22) Filed: Dec. 23, 2013

(51) Int. Cl. H01L 39/24; C23C 16/24; C23C 16/50; H01L 39/12

(52) U.S. Cl. CPC H01L 39/24; H01L 39/249; H01L 39/12; C23C 16/24; C23C 16/50

(57) ABSTRACT

A dielectric for superconducting electronics (e.g., amorphous silicon, silicon oxide, or silicon nitride) is fabricated with reduced loss tangent by fluorine passivation throughout the bulk of the layer. A fluorinant (gas or plasma) is injected into a process chamber, either continuously or as a series of pulses, while the dielectric is being formed by chemical vapor deposition on a substrate. To further reduce defects, the silicon may be deposited from a silicon precursor that includes multiple co-bonded silicon atoms, such as disilane or trisilane.

### BACKGROUND

Related fields include thin-film microwave devices with superconducting components and passivation processes for dielectrics.

At temperatures <100 mK, amorphous silicon (a-Si) is an insulating dielectric. Its low cost and ease of fabrication make it attractive as an interlayer dielectric (ILD) for superconducting interconnects and components for planar microwave devices, but its loss tangent (˜10⁸) is much larger than that of single-crystal Si (˜10⁷) at microwave frequencies (e.g., 3-300 GHz) and longer infrared frequencies (300-1000 GHz). The loss tangent is believed to be caused by defects occurring during deposition. A lower loss tangent would benefit high-frequency classical devices by reducing signal attenuation, dispersion and jitter. A lower loss tangent would benefit quantum devices, such as rapid single flux quantum (RFSQ) circuits and reciprocal quantum logic (RQL) by increasing coherence times for quantum state signals. Other candidate materials with similar challenges include silicon dioxide (SiO₂) and silicon nitride (SiN).

ILD layers are typically 300-1000 nm thick. At this thickness, many surface treatments are ineffective to remove defects from the bulk of the film. This is also an inconvenient thickness to form by the precisely controlled methods of atomic layer deposition (ALD); each ALD cycle creates a monolayer on the order of 0.1 nm thick, therefore a layer hundreds of nm thick would take too long to be cost-effective.

Hydrogenation has been observed to improve a-Si loss tangent in some cases. However, only hydrogen (H) that is strongly bonded to Si helps to reduce loss. H that is trapped in interstices of the a-Si, or that is weakly attracted to dangling bond sites of two neighboring Si atoms, can form a two-level system (TLS) that increases noise and loss. For example, early studies of Josephson-junction-based qubits for quantum computing attributed loss and decoherence primarily to extraneous TLS effects from defects in dielectrics.

TLS effects originate in electrons, atoms, and other material components that may randomly change quantum states in the presence of an oscillating electric or magnetic field such as the microwave-frequency signals transmitted in superconducting microwave devices. One type of TLS in silicon-based interlayer dielectrics is a hydrogen atom, usually from a Si precursor ligand, trapped between two dangling bonds from adjacent Si atoms. Because the Si—H bond is weak, the H easily breaks away from one Si atom and bonds to the other, and can just as easily switch back again.

Therefore, a need exists for methods to reduce the microwave-frequency loss tangent of a-Si films by reducing or eliminating defects, such as dangling bonds, in the bulk of micron-scale films as well as on the surface.

### SUMMARY

The following summary presents some concepts in a simplified form as an introduction to the detailed description that follows. It does not necessarily identify key or critical elements and is not intended to reflect a scope of invention.

Some embodiments of superconducting circuits include an ILD made of a-Si, SiO₂, or SiN passivated with fluorine (F) throughout its bulk as well as at its interfaces. F bonds so strongly with Si that it does not form a TLS even if another dangling Si bond is nearby. In some embodiments, any trapped H in the ILD only encounters isolated single dangling Si bonds, rather than neighboring pairs between which the H can randomly change its bonding state.

In some embodiments, the fluorine treatment may include co-deposition of fluorine and silicon. The fluorine treatment may include continuous or intermittent exposure to F-containing plasma or gas while the a-Si is being deposited. To further reduce the opportunities for defect formation, a precursor with Si—Si bonds already formed, such as disilane or trisilane, can be used. The a-Si can be deposited by CVD from a hydrogen-containing silicon precursor, such as Si₃H₈, with continuous or intermittent exposure to a fluorinant, such as NF₃, HF, XeF₂, SiF₄, or a fluorine-containing plasma. The deposition of a-Si and the exposure to the fluorinant may be simultaneous for at least part of the deposition cycle. Alternatively, the Si precursor and the fluorinant may be pulsed into the chamber in an alternating sequence. In some embodiments, the chamber may be purged between pulses.

Optionally, the ILD deposition may include a top sub-layer of a-Si, SiO₂, or SiN without F. Optionally, the substrate may be annealed after ILD deposition. In some embodiments, the F distribution is substantially uniform with depth in the ILD. In some embodiments, the F distribution varies by less than ±20 atomic % with depth in the ILD.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate interconnects and interlayer dielectrics.

FIG. 2 is a block diagram of an example of a CVD chamber with plasma capability.

FIGS. 3A and 3B conceptually illustrate the effect of fluorine incorporation on an amorphous Si-based layer with hydrogen TLS.

FIGS. 4A-4C conceptually illustrate the effect of the choice of Si precursor.

FIGS. 5A-5C are examples of flow profiles for CVD of a fluorinated silicon-based ILD layer.

FIG. 6 is a flowchart of an example process for fluorinating a silicon-based ILD for superconducting microwave applications.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) by default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially” contemplates up to 5% variation.

“Substrate,” as used herein, may mean any workpiece on which formation or treatment of material layers is desired. Substrates may include, without limitation, silicon, germanium, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

As used herein, a material (e.g. a dielectric material or an electrode material) will be considered to be “amorphous” if it exhibits less than or equal to 20% crystallinity as measured by a technique such as x-ray diffraction (XRD). “Interlayer dielectric,” “intermetallization dielectric,” “bulk insulator,” and “fill dielectric” are used interchangeably herein for an insulating dielectric layer that fills spaces between conducting interconnects (e.g., wiring layers, vias) or between the devices connected by the interconnects. Material properties such as “conductor,” “superconductor,” “semiconductor,” “dielectric,” and “insulator” may vary with temperature for a given material, and shall be used herein to describe the characteristics of the materials at the intended operating temperature of the device in which the materials are used. For example, “forming a superconducting layer” shall mean “forming a layer of a material expected to exhibit superconductivity at the intended operating temperature of the device being fabricated.”

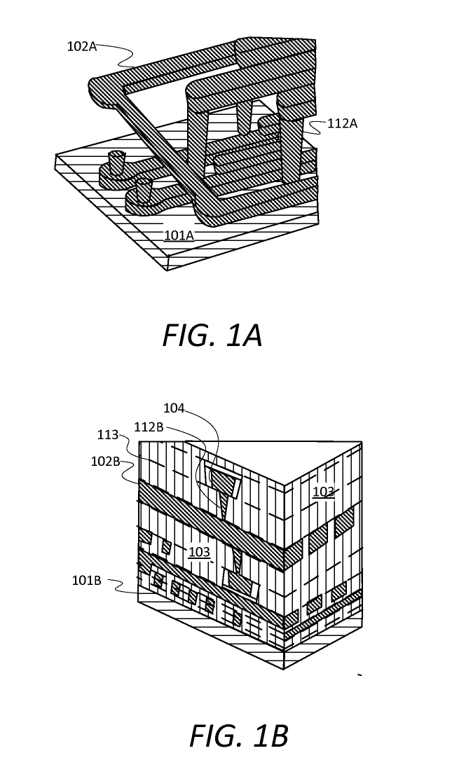

FIGS. 1A and 1B conceptually illustrate interconnects and interlayer dielectrics. FIG. 1A illustrates multiple layers of interconnects without showing the ILD, to better visualize the three-dimensional network of wirings 102a and vias 112A built up on substrate 101A. Substrate 101A may have other layers and structures below those shown. Typically, each wiring 102A begins as a blanket conductive layer formed on an ILD layer. The blanket layer is etched to form the separate conductive paths, and the resulting wiring is buried in another ILD layer. Vias 112A may be constructed similarly to wirings 102A, or alternatively they may be constructed by patterning the ILD; forming openings through the ILD and filling the openings with conductive material. Longer vias that penetrate more than one layer may be constructed as multiple segments, with the length of each segment being the thickness of one layer. Some formations may involve chemical-mechanical polishing (CMP) of either an ILD layer or a conductive layer to expose parts of buried structures. In superconducting microwave devices, the conductive elements (wirings and vias) may be any suitable superconducting material, such as aluminum (Al), niobium (Nb), Nb alloys, Nb nitride, ceramic superconductors, or organic superconductors.

FIG. 1B is a schematic cutaway view of several interconnect and device layers. Here, the ILD 103 is shown between the structures; heavy dotted lines 113 delineate the separately formed layers. The illustrated structures include some wirings 102B and vias 112B, and also some components 104 (e.g., transistors, capacitors, switches, resistors, resonators; in a superconducting device, the components may include Josephson junctions).

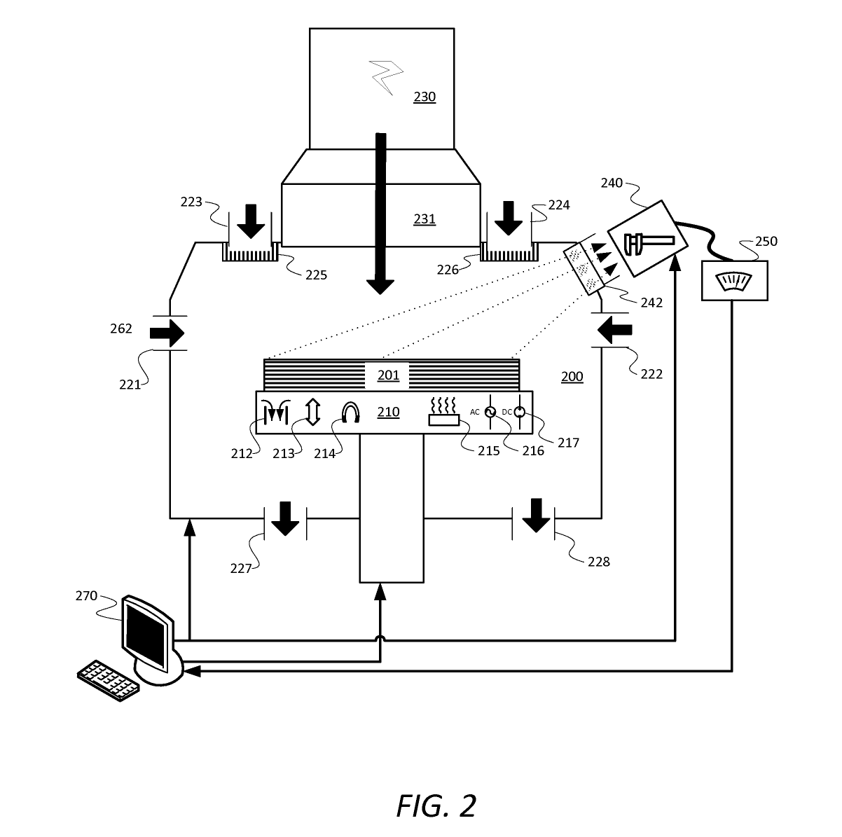

FIG. 2 is a block diagram of an example of a CVD chamber with plasma capability. Inside CVD chamber 200, substrate 201 is held by a substrate holder 210. Substrate holder 210 may be configured with vacuum 212 (for example, a vacuum chuck to grip the substrate); motion 213 in any direction, which may include tilt and rotation; a magnetic field source 214; heater or temperature control 215; or sources of AC 216 or DC 217 bias voltage. Chamber 200 also has gas inlets 221, 222, 223, 224 for CVD precursors, buffer gases, and purge gases. Exhausts 227, 228 may be coupled to vacuum pumps to remove gases from chamber 200. Some of the inlets may feed through one or more diffusers or “showerheads” 225, 226. In some embodiments, remote plasma chamber 230 may generate reactive species, such as ions, that enter chamber 200 through input adapter 231. In some embodiments, a direct plasma may be generated at or near the surface of substrate 201. Measurement system 240 may monitor substrate 201 through measurement ports 242. The measurements from measurement system 240 may be collected by a monitoring system 250.

Hydrogen, as discussed above, passivates some defects in a-Si, SiO₂, and SiN. When depositing Si from a hydrogen-containing precursor such as silane, disilane, or trisilane, some hydrogenation of the a-Si is likely to occur when ligands fail to detach fully and, instead of leaving the chamber with the purge gas, are trapped in the a-Si layer.

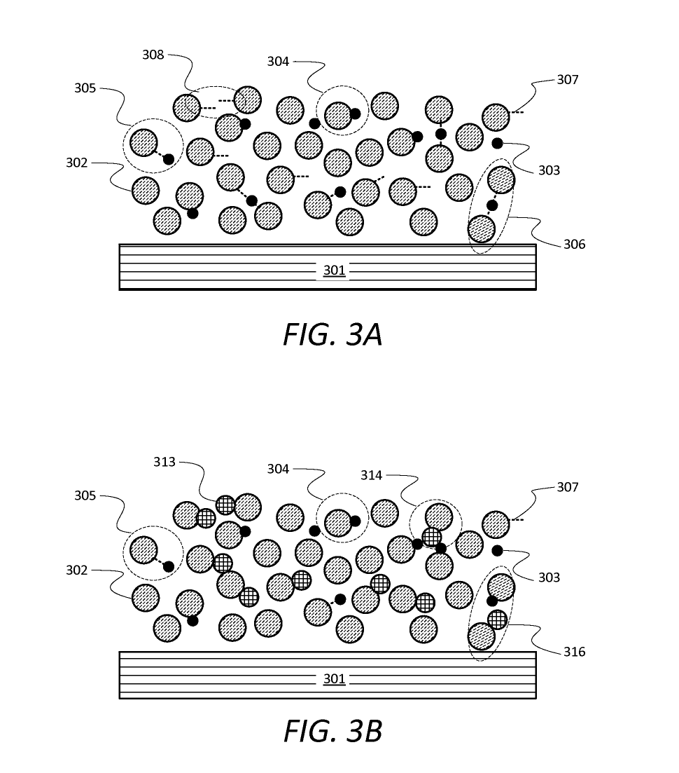

FIGS. 3A and 3B conceptually illustrate the effect of fluorine incorporation on an amorphous Si-based layer with hydrogen TLS. This illustration is not intended to represent the hydrogenation level, defect density, or exact structure of any particular material, but merely to introduce the graphic symbols for the various elements and bonds. In particular, the layer is illustrated as a-Si but the concepts are also applicable to SiO₂ and SiN.

In FIG. 3A, Si atoms 302 and H atoms 303 are randomly arranged in the amorphous layer on substrate 301, which may have underlying layers and structures such as interconnects or device layers. Some Si atoms have dangling bond sites 307. Some neighboring Si atoms have pairs of adjacent, opposing dangling bonds 308. The hydrogen may be from trapped ligands of H-containing Si CVD precursors such as silane, disilane or trisilane, or from an H-containing ambient in which the Si was deposited, or some other source. In other superconducting-device ILD materials, such as SiO₂ and SiN, the H may alternatively be a trapped ligand of the oxidant or nitridant.

A strongly bonded Si—H pair 304 is represented by tangential contact of the Si and H. A weakly bonded Si—H pair 305 is represented by a dotted-line connection. In some cases, an H atom is weakly bonded to two neighboring Si atoms (e.g., a pair with adjacent opposing dangling bonds 307) by a shared weak bond 306. The strongly bonded Si—H pair 304 will not form a TLS, but weakly bonded pairs 305 and 306 may become TLS sites. The H atom in a shared bond 306 may randomly change its state from weakly bonded to one of the neighboring Si atoms to weakly bonded to the other, causing noise, loss, and decoherence of propagating quantum signals (e.g., from qubits). Unbonded H atoms may also exhibit TLS behavior; alternatively, if they encounter each other while migrating through the surrounding material, they may bond together into H₂ and outgas from the layer. The dangling bonds and hydrogen atoms are distributed throughout the bulk of the layer.

In FIG. 3B, the layer has been bulk-passivated with a halogen such as fluorine. Fluorine 313 forms very strong bonds with Si 302 and is much heavier than H 303. Therefore, it is far more resistant than H to quantum-tunneling triggers such as the passage of propagating signals in the microwave or far-infrared frequencies. Even if another dangling bond is nearby, bonded F does not operate as a TLS. Few, if any, weak Si—H bonds 305 remain. Ideally, any trapped H in the layer may only bond to one Si atom (e.g., configuration 316) rather than being shared between two (e.g., configuration 306 in FIG. 3A).

Some known F passivation techniques may not be suitable for the ILD in a superconducting device. For example, because the defects are distributed throughout the bulk of the layer, surface passivation treatments may leave many of the TLS sites behind in a thick layer such as an ILD. As another example, some treatments that penetrate further below the surface, such as ion implantation, can create additional defects because the ion impacts damage the surface of the impacted layer.

In some embodiments, the exposure to the fluorinant begins before the dielectric layer is fully formed, e.g., before the a-Si deposition is complete. The a-Si deposition and the fluorinant exposure may be simultaneous during at least part of the process. Alternatively, partial a-Si depositions may be alternated with fluorinant exposure. This approach distributes the fluorine throughout the bulk of the layer to passivate defects wherever they may arise, without causing damage that may create more defects.

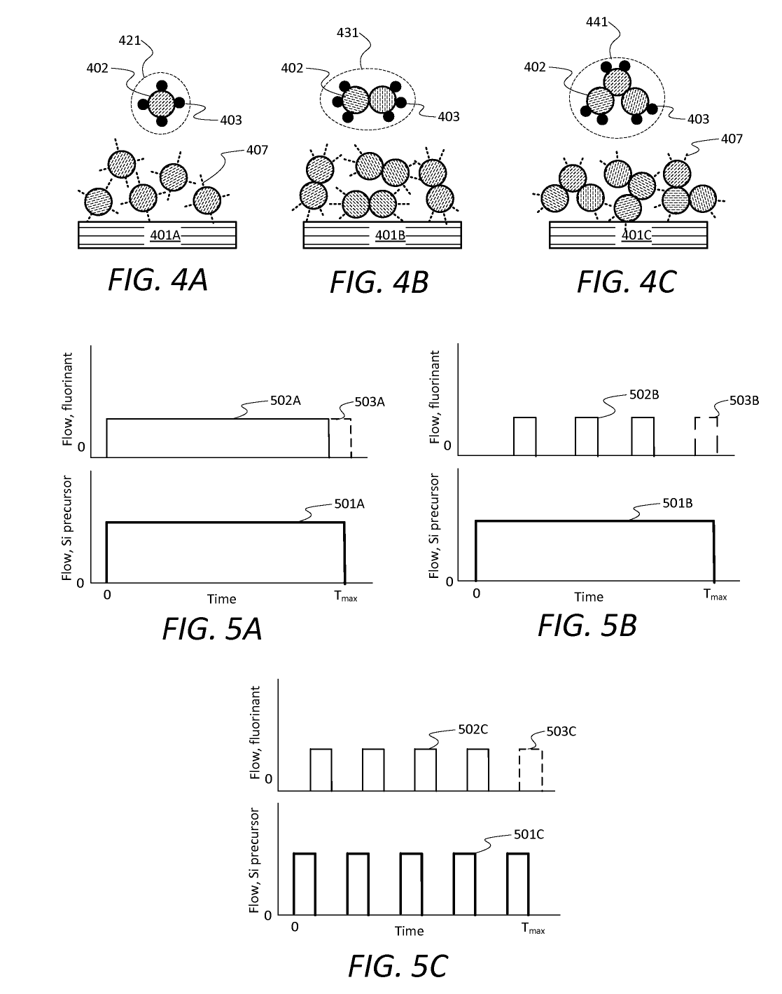

FIGS. 4A-4C conceptually illustrate the effect of the choice of Si precursor. These drawings are purely symbolic; some details, such as bond angles, may not be realistically represented. Each atom of Si has 4 valencies (available bonding sites). In FIG. 4A, each molecule of silane (SiH₄) 421 has one Si atom 402 and 4 H atoms 403. When Si is deposited on substrate 401A from a silane precursor, depending on the deposition conditions, some of the H atoms may remain to hydrogenate the material or, as illustrated here for simplicity, all the H atoms may detach from the Si and recombine as H₂ to be purged from the chamber. This leaves each Si atom with 4 emptied valencies. The valencies may be refilled by bonding with other Si atoms, or with materials on the surface of substrate 401, or (if SiO₂ or SiN is being formed) with oxygen or nitrogen. Some of the valencies, however, may remain unfilled as dangling bonds.

In FIG. 4B, each molecule of disilane (Si₂H₆) 421 has 2 Si atoms 402 and 6 H atoms 403, and one valency on each of the Si atoms is bonded to the other Si atom. When Si is deposited on substrate 401B from a disilane precursor, the bonded Si atoms tend to remain bonded even if all the H atoms detach. Thus each Si atom on substrate 401B has 3 emptied valencies, compared to 4 for each Si atom on substrate 401A. All other factors being equal, the deposited material from disilane 431 has only % as many potential dangling bonds (i.e., opportunities to form defects) as the deposited material from silane 421.

In FIG. 4C, each molecule of trisilane (Si₃H₈) 441 has 3 Si atoms 402 and 8 H atoms 403, and two valencies on each of the Si atoms are bonded to another Si atom. When Si is deposited on substrate 401C from a trisilane precursor, the bonded Si atoms tend to remain bonded even if all the H atoms detach. Thus each Si atom on substrate 401C has 2 emptied valencies, compared to 4 for each Si atom on substrate 401A. All other factors being equal, the deposited material from disilane 441 has only ½ as many potential dangling bonds (i.e., opportunities to form defects) as the deposited material from silane 421.

In some embodiments, the Si is deposited from a precursor having at least two interbonded Si atoms before or during the fluorine treatment.

FIGS. 5A-5C are examples of flow profiles for CVD of a fluorinated silicon-based ILD layer. The fluorinate may be either a fluorine-containing gas or a fluorine-containing plasma. In FIG. 5A, both the Si precursor 501A and the fluorinant 502A, 503A flow into the CVD chamber continuously. The fluorinant flow may end before the Si is fully deposited (line 502A) or it may continue until or beyond the end of the Si flow (line 503A). Neither flow rate necessarily needs to be uniform; for example, it may ramp up or down linearly or non-linearly with time. The resulting distribution of fluorine within the ILD layer may be substantially uniform with depth. The peak flow rate of the Si precursor may be about 75-125 sccm, and the peak flow rate of the fluorinant may be about 20-30 sccm.

In FIG. 5B, Si precursor flow 501B is continuous and fluorinant flow 502B, 503B is a series of pulses. The fluorinant pulses may end before the Si is fully deposited (line 502B) or they may continue until or beyond the end of the Si flow (line 503B). There may be any suitable number of pulses, they may ramp up or down linearly or non-linearly with time, and they may differ in height or spacing. For example, the pulse length may be 0.1-20 seconds and the separation between pulses may be 0.1-200 seconds. In some embodiments, the fluorine distribution with depth may be uniform ±20 atomic %.

In FIG. 5C, Si precursor flow 501C and fluorinant flow 502C, 503C are a series of pulses. The fluorinant pulses may end before the Si is fully deposited (line 502C) or they may continue until or beyond the end of the Si flow (line 503C). For either flow, there may be any suitable number of pulses, they may ramp up or down linearly or non-linearly with time, and they may differ in height or spacing. Between pulses, the chamber may optionally be purged using an inert purge gas such as argon. In some embodiments, the fluorine distribution with depth may be uniform ±20 atomic %.

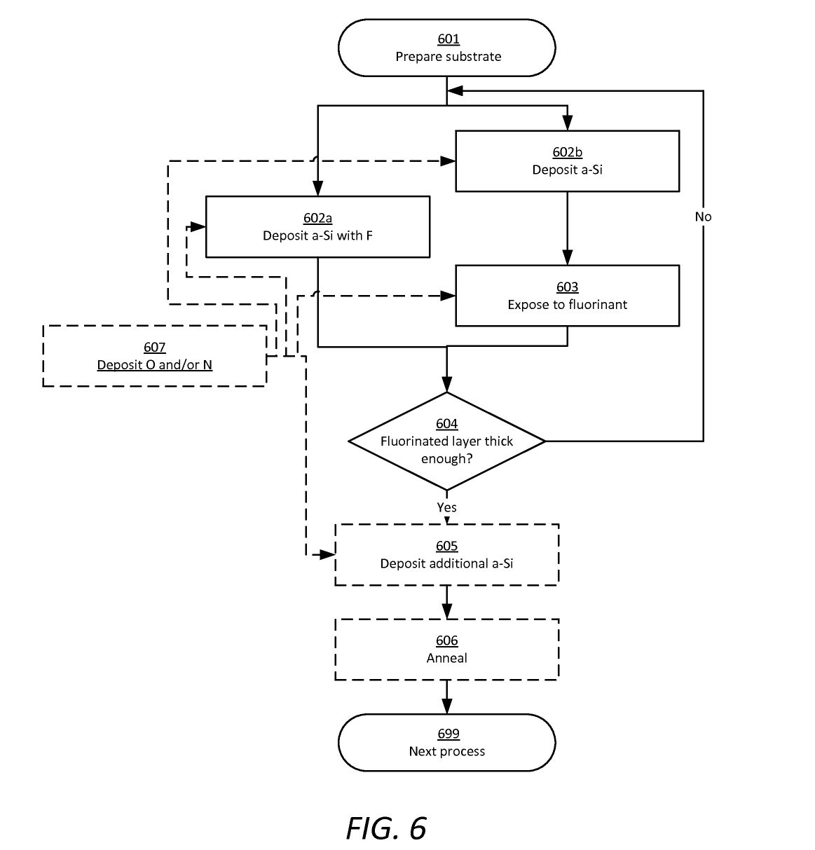

FIG. 6 is a flowchart of an example process for fluorinating a silicon-based ILD for superconducting microwave applications. Step 601 of preparing a substrate may include a pre-clean, or the patterning or other partial removal of an underlying layer. Substrate preparation 601 may be followed by either step 602A of co-depositing the a-Si precursor and the fluorinant, or by a sequence of step 602b of depositing the a-Si and step 603 of exposing the a-Si to a fluorinant gas or plasma. Either type of deposition sequence may be repeated until a desired thickness of the fluorinated layer is reached at step 604. For example, for an ILD the desired thickness may be 300-1000 nm, but these techniques may also be used to deposit tunnel barriers (˜0.5-3 nm) or gate dielectrics (5-30 nm). After fluorinated layer completion 604, optional step 605 of depositing additional non-fluorinated a-Si, with or without optional step 606 of annealing the finished layer, may precede next process 699. Optionally, if the layer is being formed is SiO₂ or SiN, a step 607 of adding the oxygen and/or nitrogen may be concurrent with any part of the a-Si or F deposition.

In some embodiments, the deposition temperature may be between about 350 C and 650 C, the chamber pressure may be between about 0.1 Torr and 100 Torr, the Si precursor may be silane, disilane, or trisilane, the total deposition time may be 2-5000 seconds.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method, comprising:
forming a first superconducting layer on a substrate; and
forming a first dielectric layer over the first superconducting layer;
wherein the forming of the first dielectric layer comprises depositing silicon by using chemical vapor deposition and exposing the silicon to a fluorinant; and
wherein the exposing of the silicon to the fluorinant begins before the depositing of the silicon terminates.

2. The method of claim 1, wherein a precursor used in the chemical vapor deposition comprises at least two silicon atoms bonded to each other.

3. The method of claim 1, wherein the fluorinant comprises a fluorine-containing gas.

4. The method of claim 1, wherein the fluorinant comprises NF₃, HF, XeF₂, or SiF₄.

5. The method of claim 1, wherein the fluorinant comprises a fluorine-containing plasma.

6. The method of claim 1, further comprising forming a second dielectric layer over the first dielectric layer; wherein the forming of the second dielectric layer comprises chemical vapor deposition of non-fluorinated silicon.

7. The method of claim 1, wherein the exposing to the fluorinant and the depositing of the silicon are simultaneous for at least part of a deposition cycle.

8. The method of claim 1, wherein the fluorinant is injected into a process chamber containing the substrate as a plurality of pulses.

9. The method of claim 8, wherein a duration of the pulses is between about 0.1 and about 20 seconds.

10. The method of claim 8, wherein the pulses are separated by between about 0.1 and about 200 seconds.

11. The method of claim 8, further comprising a purge of the process chamber after at least one of the pulses.

12. The method of claim 1, wherein the first dielectric layer is formed at a temperature between about 350 C and about 650 C.

13. The method of claim 1, wherein the first dielectric layer is formed at a pressure between about 0.1 Torr and about 100 Torr.

14. The method of claim 1, wherein the forming of the first dielectric layer continues for a time between about 2 seconds and about 5000 seconds.

15. The method of claim 1, wherein a flow rate of a precursor used in the chemical vapor deposition of the silicon is between about 75 sccm and 125 sccm.

16. The method of claim 1, wherein a flow rate of the fluorinant is between about 20 sccm and 30 sccm.

17. The method of claim 1, wherein a fluorine concentration in the first dielectric layer is substantially uniform with depth.

18. The method of claim 1, wherein a fluorine concentration in the first dielectric layer varies by less than ±20 atomic % with depth.

19. A superconducting device, comprising:
a structure, wherein the structure comprises a superconducting material; and
an insulating layer in contact with the structure on at least one side;
wherein the insulating layer comprises amorphous silicon and fluorine; and
wherein a concentration of the fluorine is within ±20 atomic % of a constant value throughout the thickness of the insulating layer.

20. The superconducting device of claim 19, wherein the concentration of the fluorine is substantially uniform throughout the thickness of the insulating layer.
